(19) United States
(12) Patent Application Publication
(10) Pub. No.: US 2020/0224305 A1
(43) Pub. Date: Jul. 16, 2020

(54) DEPOSITION SYSTEM, DEPOSITION APPARATUS, AND METHOD OF OPERATING A DEPOSITION SYSTEM

(71) Applicant: Applied Materials, Inc., Santa Clara, CA (US)

(72) Inventors: Stefan BANGERT, Steinau (DE); Matthias KREBS, Alzenau (DE)

(73) Assignee: Applied Materials, Inc., Santa Clara, CA (US)

(21) Appl. No.: 15/754,920

(22) PCT Filed: Apr. 12, 2017
(86) PCT No.: PCT/EP2017/058829

§ 371 Date: Feb. 23, 2018

(30) Foreign Application Priority Data
Mar. 17, 2017 (EP) PCT/EP2017/056381

(51) Int. Cl. C23C 14/54; C23C 14/24; C23C 14/04

(52) U.S. Cl. CPC C23C 14/541; C23C 14/042; C23C 14/24

(57) ABSTRACT

A deposition system for depositing evaporated material on a substrate is described. The deposition system includes a vapor source having one or more vapor outlets; a shield; and a cooling device for cooling the shield, wherein the vapor source is movable to an idle position in which the one or more vapor outlets are directed toward the shield. Further, a deposition apparatus with a deposition system as well as a method of operating a deposition system are described.

### TECHNICAL FIELD

The present disclosure relates to deposition systems configured for depositing an evaporated material, particularly an evaporated organic material, on one or more substrates. Embodiments of the present disclosure further relate to a deposition apparatus with a deposition system for depositing an evaporated material on a substrate. Further embodiments relate to methods of operating a deposition system, particularly for depositing an evaporated material on a substrate in a vacuum processing chamber.

### BACKGROUND

Organic evaporators are a tool for the production of organic light-emitting diodes (OLED). OLEDs are a special type of light-emitting diode in which the emissive layer comprises a thin-film of certain organic compounds. Organic light emitting diodes (OLEDs) are used in the manufacture of television screens, computer monitors, mobile phones, other hand-held devices, e.g. for displaying information. OLEDs can also be used for general space illumination. The range of colors, brightness and viewing angles of OLED displays may be greater than that of traditional LCD displays because OLED pixels directly emit light and do not involve a back light. Therefore, the energy consumption of OLED displays is considerably less than that of traditional LCD displays. Further, the fact that OLEDs can be manufactured onto flexible substrates results in further applications.

Typically, the evaporated material is directed toward the substrate by one or more outlets of a vapor source. For example, the vapor source may be provided with a plurality of nozzles that are configured for directing plumes of evaporated material toward the substrate. The vapor source may be moved relative to the substrate for coating the substrate with the evaporated material.

A stable plume of evaporated material from the one or more vapor outlets of the vapor source may be beneficial, in order to deposit a material pattern with a predetermined uniformity on the substrate. After start-up of the vapor source, it may take some time for the vapor source to stabilize. A frequent shut-down and start-up of the vapor source may therefore not be desirous, and the vapor source may be kept running also in idle periods. There may be a risk that, during such idle periods, a wall of the vacuum processing chamber may get coated by evaporated material (“sprinkle coating”).

Accordingly, it would be beneficial to provide a deposition system configured for depositing an evaporated material on a substrate in an accurate manner, while reducing a sprinkle coating on surfaces of the system.

### SUMMARY

In view of the above, a deposition system, a deposition apparatus as well as methods of operating a deposition system according to the independent claims are provided. Further advantages, features, aspects and details are apparent from the dependent claims, the description and drawings.

According to one aspect of the present disclosure, a deposition system is provided. The deposition system includes a vapor source having one or more vapor outlets, the vapor source movable between a deposition position and an idle position, a shield, and a cooling device positioned to cool the shield.

The vapor source may be movable to the idle position in which the one or more vapor outlets are directed toward the shield.

According to another aspect of the present disclosure, a deposition apparatus is provided. The deposition apparatus includes a vacuum processing chamber with a first deposition area for arranging a substrate and a second deposition area for arranging a second substrate, and a deposition system arranged in the vacuum processing chamber, wherein a vapor source of the deposition system is movable past the first deposition area, rotatable between the first deposition area and the second deposition area and movable past the second deposition area. The deposition system includes a shield and a cooling device for cooling the shield.

According to a further aspect of the present disclosure, a method of operating a deposition system is provided. The method includes directing evaporated material from one or more vapor outlets of a vapor source toward a substrate, and moving the vapor source to an idle position in which evaporated material from the one or more vapor outlets is directed toward a cooled shield.

According to a further aspect of the present disclosure, a cooled shield for a deposition system described herein is provided.

The disclosure is also directed to an apparatus for carrying out the disclosed methods including apparatus parts for performing the methods. The method may be performed by way of hardware components, a computer programmed by appropriate software, by any combination of the two or in any other manner. Furthermore, the disclosure is also directed to operating methods of the described apparatus. The disclosure includes a method for carrying out every function of the apparatus.

### BRIEF DESCRIPTION OF THE DRAWINGS

So that the manner in which the above recited features of the disclosure described herein can be understood in detail, a more particular description, briefly summarized above, may be had by reference to embodiments. The accompanying drawings relate to embodiments of the disclosure and are described in the following:

FIG. 1A and FIG. 1B show schematic views of a deposition system according to embodiments described herein in a deposition position (FIG. 1A) and in an idle position (FIG. 1B);

FIG. 2 shows a perspective view of a shield of a deposition system according to embodiments described herein;

FIG. 3 shows a schematic sectional view of a part of a deposition system according to embodiments described herein;

FIG. 4 shows a schematic view of a deposition apparatus with a deposition system according to embodiments described herein;

FIG. 5 illustrates subsequent stages (a)-(f) of a method of operating a deposition system according to embodiments described herein;

FIG. 6 shows a schematic sectional view of a deposition system according to embodiments described herein; and

FIG. 7 is a flow diagram illustrating a method of operating a deposition system according to embodiments described herein.

### DETAILED DESCRIPTION OF EMBODIMENTS

Reference will now be made in detail to the various embodiments of the disclosure, one or more examples of which are illustrated in the figures. Within the following description of the drawings, the same reference numbers refer to same components. In the following, the differences with respect to individual embodiments are described. Each example is provided by way of explanation of the disclosure and is not meant as a limitation of the disclosure. Further, features illustrated or described as part of one embodiment can be used on or in conjunction with other embodiments to yield yet a further embodiment. It is intended that the description includes such modifications and variations.

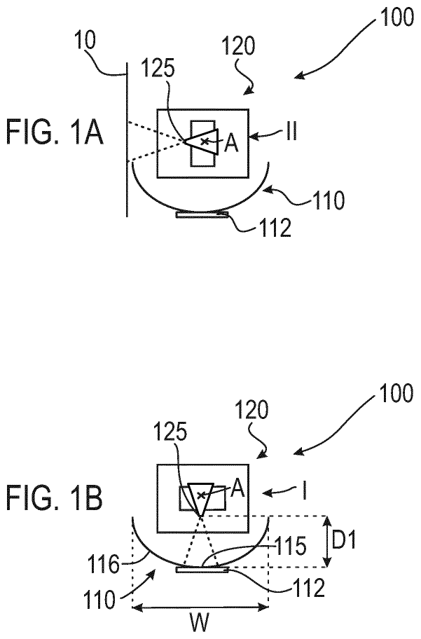

FIG. 1A is a schematic view of a deposition system 100 according to embodiments described herein. The deposition system 100 includes a vapor source 120 having one or more vapor outlets 125. The vapor source 120 is in a deposition position (II) for coating a substrate 10. In the deposition position, the one or more vapor outlets are directed toward a deposition area in which the substrate 10 is arranged.

FIG. 1B is a schematic view of the deposition system 100 of FIG. 1A, wherein the vapor source 120 is in an idle position (I). In the idle position, the one or more vapor outlets 125 are directed toward a shield 110.

The vapor source 120 may be movable from the deposition position (II) into the idle position (I) in which the one or more vapor outlets 125 are directed toward the shield 110 and/or from the idle position (I) into the deposition position (II) in which the one or more vapor outlets 125 are directed toward the deposition area.

The vapor source 120 may be configured as an evaporation source for depositing an evaporated material on the substrate 10 that is arranged in the deposition area. In some embodiments, the vapor source 120 includes one or more crucibles and one or more distribution pipes, wherein the one or more vapor outlets 125 may be provided in the one or more distribution pipes. Each crucible may be in fluid connection with an associated distribution pipe. Evaporated material may stream from the crucible into the associated distribution pipe. Plumes of evaporated material may be directed from the one or more vapor outlets of the distribution pipe into the deposition area, when the deposition system is in the deposition position.

In FIG. 1A, evaporated material is directed from the one or more vapor outlets 125 toward the substrate 10. A material pattern may be formed on the substrate. In some embodiments, a mask (not shown) is arranged in front of the substrate 10 during deposition, i.e. between the substrate 10 and the vapor source 120. A material pattern corresponding to an opening pattern of the mask can be deposited on the substrate. In some embodiments, the evaporated material is an organic material. The mask may be a fine metal mask (FMM) or another type of mask, e.g. an edge exclusion mask.

After deposition on the substrate 10, the vapor source 120 may be moved into the idle position (I) that is exemplarily depicted in FIG. 1B. The movement of the vapor source 120 into the idle position (I) may be a relative movement between the vapor source 120 and the shield 110. In the idle position, the one or more vapor outlets are directed toward a surface of the shield 110.

In some embodiments, the vapor source 120 is not deactivated in the idle position and/or during the movement into the idle position. Therefore, evaporated material may be directed from the one or more vapor outlets 125 toward the shield 110 and condense on a surface of the shield, when the vapor source is in the idle position (I). By continuing with the evaporation also in the idle position, e.g. during idle times of the system, a vapor pressure in the vapor source may be kept essentially constant and the deposition may continue later without a stabilization time of the vapor source.

The shield 110 may be formed such that 80% or more, particularly 90% or more, more particularly 99% or more of the evaporated material from the one or more vapor outlets 125 is directed toward a surface of the shield 110, when the vapor source 120 is in the idle position (I). A contamination of other surfaces in the vacuum processing chamber can be reduced or avoided, when the vapor source 120 is in the idle position, because the evaporation plumes may be blocked and shielded by the shield 110. In particular, a coating of the chamber walls, of devices arranged in the vacuum processing chamber, of mask carriers and of substrate carriers, can be reduced or avoided. In some embodiments, a surface of the shield 110 may be large, e.g. 0.5 m² or more, particularly 1 m² or more, more particularly 2 m² or more, in order to make sure that most of the evaporated material condenses on the surface of the shield and not on another surface in the idle position.

The vapor source 120 may be moved into the idle position (I) for at least one or more of the following purposes: (i) for heating-up the vapor source; (ii) for stabilizing the vapor source, e.g. during heat-up, until an essentially constant vapor pressure forms in the vapor source; (iii) for service or maintenance of the vapor source; (iv) for shut-down of the vapor source, e.g. during cool-down; (v) for cleaning of the vapor source, e.g. for cleaning of the one or more vapor outlets and/or for cleaning of shaper shields arranged in front of the vapor outlets; (vi) during mask and/or substrate alignment; (vii) during waiting times and in idle periods. For example, the idle position may be used as a park position of the deposition system in idle periods of the system. In some embodiments, the vacuum processing chamber and/or a mask which may be arranged in the deposition area may be protected against sprinkle coating by the shield 110, e.g. during the movement of the source into the idle position.

According to embodiments described herein, a cooling device 112 for cooling of the shield 110 is provided. The shielding effect of the shield can be improved by reducing the temperature of the shield with the cooling device. Further, the heat radiation from the shield toward the vapor source, toward the mask and/or toward the substrate can be reduced by cooling the shield 110. Thermally caused movements can be reduced or avoided and the deposition quality may improve.

The evaporated material may have a temperature of hundreds of degrees, e.g. 100° C. or more, 300° C. or more, or 500° C. or more. Accordingly, the shield 110 may heat up in the idle position, when evaporated material condenses on a surface of the shield. In some embodiments, the vapor source 120 may remain in the idle position over a considerable period of time, e.g. over tens of seconds for alignment or cleaning, or over minutes for heat-up and service of the vapor source. A temperature of the shield 110 can be reduced by the cooling device 112, and a heat radiation from the shield toward the vapor source and toward the mask can be reduced. For example, the temperature of the shield may be kept at 100° C. or less. The deposition quality can be improved, since a thermal movement of the mask is reduced. It is to be noted that, in some embodiments, the mask may have structures in the range of a few microns so that a constant temperature of the mask is beneficial for reducing thermally caused movements of the mask structures. Further, by cooling a surface of the shield 110, a condensation of evaporated material on the shield can be facilitated.

The cooling device may include at least one or more of: cooling lines or cooling channels connected to the shield; a fluid cooling such as a water cooling; a gas cooling such as an air cooling and/or a thermoelectric cooling. In some embodiments, the cooling device includes a cooling circuit with cooling channels attached to or integrated in the shield. A cooling fluid such as water may circulate in the cooling circuit.

In some embodiments, cooling channels may be provided at a front portion 115 of the shield. The one or more vapor outlets 125 may be directed toward the front portion 115 in the idle position so that the front portion 115 may be subject to most of the heat load in the idle position. The shield 110 may further include one or more side portions 116 arranged adjacent to the front portion 115. The one or more side portions 116 may be provided for shielding evaporated material during the movement of the vapor source into the idle position. The mask may be protected against sprinkle coating during the movement of the vapor source, as the one or more side portions 116 may block the evaporated material during the movement of the vapor source. In some embodiments, two side portions 116 are provided on two opposite sides of the front portion 115. The side portions 116 may be curved.

In some embodiments, which may be combined with other embodiments described herein, the deposition system 100 may include a first drive configured for moving the vapor source 120 together with the shield 110 along a source transportation path P. For example, the source transportation path may extend past the deposition area in which the substrate 10 is arranged. The vapor source 120 may be moved together with the shield 110 past the substrate 10, e.g. at an essentially constant speed. For example, the shield 110 and the vapor source 120 may be arranged on a source support, e.g. on a source cart, which is configured to be guided along a track. In some embodiments, the first drive may be configured for moving the source support along tracks along the source transportation path P, wherein the vapor source and the shield may be supported by the source support. In some embodiments, the source support may be transported along the tracks without contacting the tracks, e.g. via a magnetic levitation system.

In particular, the first drive may be configured for linearly moving the vapor source together with the shield along tracks which extend along the source transportation path P.

When the shield 110 is movable together with the vapor source 120 along the source transportation path P, a distance between the vapor source and the shield may be kept small or constant during the deposition process. For example, a maximum distance between the vapor source and the shield during the deposition may be 0.5 m or less, particularly 0.2 m or less.

In some embodiments, which may be combined with other embodiments described herein, the deposition system may further include a second drive for moving the vapor source 120 relative to the shield 110 to the idle position (I). In other words, the first drive may be configured for moving the vapor source together with the shield, and the second drive may be configured for moving the vapor source relative to the shield. In the embodiment of FIG. 1A and FIG. 1B, the vapor source 120 is rotatable relative to the shield 110 from the deposition position into the idle position around a rotation axis A. For example, the vapor source may be rotated from the deposition position into the idle position by an angle of 45° or more and 135° or less, particularly about 90°.

A rotation of the vapor source may include any type of swinging or pivoting movement of the vapor source which leads to a direction change of the evaporation direction of the one or more vapor outlets. In particular, the rotation axis may intersect the vapor source centrally, may intersect a periphery of the vapor source, or may not intersect the vapor source at all.

A “rotation of a device” as used herein can be understood as a movement of the device from a first orientation to a second orientation different from the first orientation.

Further, the vapor source may be movable from the idle position to the deposition position by rotating the vapor source, e.g. by rotating the vapor source back toward the deposition area, e.g. by an angle of about 90°, or by rotating the vapor source toward a second deposition area where a second substrate may be arranged, e.g. by an angle of about 90°.

The rotation axis A may be an essentially vertical rotation axis. The vapor source 120 may be rotatable around the essentially vertical rotation axis between the idle position and the deposition position. In particular, the vapor source 120 may include one, two or more distribution pipes which may extend in an essentially vertical direction, respectively. A plurality of vapor outlets may be provided along the length of each distribution pipe, i.e. along the essentially vertical direction. A compact and space-saving deposition system can be provided.

In some embodiments, which may be combined with other embodiments described herein, a radially inner surface of the shield 110 may be directed toward the vapor source. In particular, the shield 110 may include a curved portion which extends partially around the vapor source. For example, the shield may include two side portions 116 which may be curved and which may extend partially around the vapor source. In some embodiments, the curved portion of the shield may extend partially around the rotation axis A of the vapor source.

Due to the curvature of the vapor shield, the shielding effect of the shield may be improved during the rotation of the shield 110 around the rotation axis A. In particular, a distance between the one or more vapor outlets and the surface of the shield may remain substantially constant during a rotation of the shield.

In some embodiments, at least a portion of the shield is shaped as a part of a cylinder surface which extends around the vapor source, particularly around the rotation axis A of the vapor source.

In some embodiments, the curved portion of the shield 110 may extend around the vapor source 120 by an angle of 30° or more, particularly 60° or more, more particularly 90° or more. Accordingly, when the vapor source rotates by an angle of 30° or more, particularly 60° or more, more particularly 90° or more, from the deposition position to the idle position, the evaporated material may be essentially continuously shielded by the shield. A contamination of the vacuum processing chamber can be reduced and a heat radiation into the vacuum processing chamber can be decreased.

In some embodiments, which may be combined with other embodiments described herein, a distance D1 between the one or more vapor outlets and the shield may be 5 cm or more and 30 cm or less, when the vapor source is in the idle position. In particular, the distance D1 may be 5 cm or more and 10 cm or less. The shielding effect of the shield 110 can be further improved by providing a small distance between the shield and the one or more vapor outlets. Further, a more compact cooling device can be used, because most of the heat load of the vapor source is localized in a small portion of the shield in the idle position.

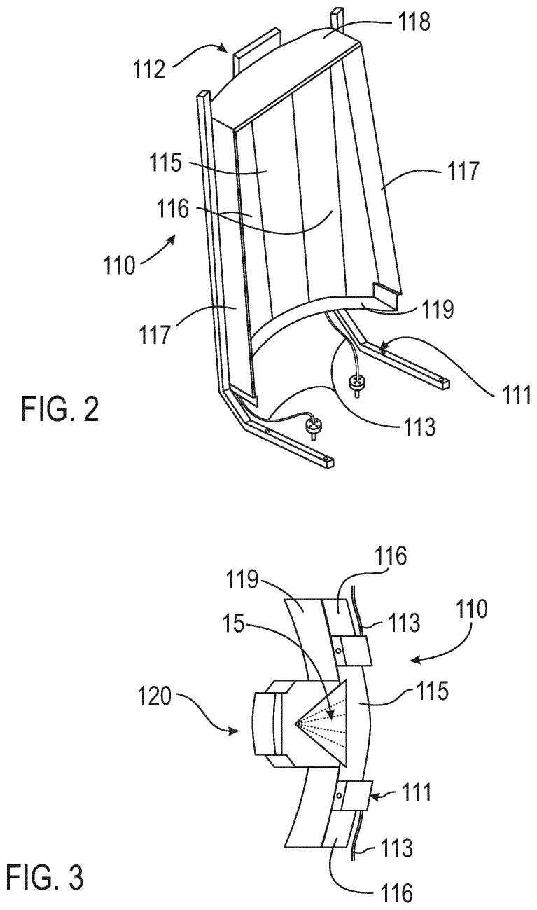

FIG. 2 is a perspective view of a shield 110 of a deposition system according to embodiments described herein. The shield 110 may be similar to the shield of the embodiment of FIG. 1A, so that reference can be made to the above explanations, which are not repeated here.

The shield 110 may be arranged adjacent to a vapor source such that the one or more vapor outlets of the vapor source are directed toward a surface of the shield when the vapor source is in the idle position. A cooling device 112 may be provided for cooling at least a portion of the shield. For example, a front portion 115 of the shield may be cooled with the cooling device 112. The front portion 115 can be understood as a portion of the shield the one or more vapor outlets are directed to when the vapor source is in the idle position. In some embodiments, the front portion 115 is a center portion of the shield 110.

The shield 110 may be curved and may extend partially around an area where the vapor source is to be arranged. In particular, the shield may include one or more curved portions. For example, the shield may include the front portion 115 and two side portions 116 which are arranged adjacent to the front portion 115 on two opposite sides of the front portion 115. The two side portions 116 may be curved around the area where the vapor source is to be arranged.

In some embodiments, which may be combined with other embodiments described herein, the shield 110 may include a plurality of shielding portions formed as sheet elements, e.g. as metal sheets. For example, the shield may include one or more of: a bottom portion 119 which extends in an essentially horizontal orientation at a position below the one or more vapor outlets; a top portion 118 which extends in an essentially horizontal orientation at a position above the one or more vapor outlets; the front portion 115 which may extend in an essentially vertical orientation in front of the one or more vapor outlets, when the vapor source is in the idle position; the two curved side portions which may extend in an essentially vertical orientation on two opposite sides of the front portion 115; and/or two outer portions 117 which may extend in an essentially vertical orientation and form a side edge of the shield.

A bottom portion 119 may be arranged below the lowermost outlet of the one or more vapor outlets. The bottom portion 119 may shield evaporated material sinking down toward a ground of the vacuum processing chamber when the vapor source is in the idle position. The bottom portion 119 may extend in an essentially horizontal direction. In some embodiments, the bottom portion 119 may form a bottom edge of a sheet portion of the shield. In some embodiments, the bottom portion may have an essentially annular shape extending around the vapor source, particularly around the rotation axis of the vapor source.

A top portion 118 may be arranged above the uppermost outlet of the one or more vapor outlets. The top portion 118 may shield evaporated material directed upward toward an upper area of the vacuum processing chamber when the vapor source is in the idle position. The top portion 118 may extend in an essentially horizontal direction. In some embodiments, the top portion 118 may form a top surface of a sheet portion of the shield. In some embodiments, the top portion may have the shape of a top plate.

The front portion 115 may be arranged in front of the one or more vapor outlets when the vapor source is in the idle position. The front portion 115 may block a main portion of the evaporated material when the shield is in the idle position. Accordingly, according to some embodiments, the front portion 115 may be cooled with the cooling device 112. For example, the cooling device 112 may include cooling channels 113 for a cooling fluid which may be arranged adjacent to or integrated in the front portion. In some embodiments, the front portion 115 may extend in an essentially vertical orientation.

In some embodiments, the shield 110 may include a support frame 111. The sheet portions of the shield 110 may be fixed to the support frame 111. In particular, the support frame 111 may be configured for holding and supporting at least one or more of the front portion, the side portions and/or the outer portions. The support frame 111 may be supported on a source support which is configured for supporting and transporting the vapor source together with the shield. At least a part of the cooling channels 113 may extend along the support frame 111 of the shield 110. For example, the cooling channels 113 may be fixed to or integrated in the support frame 111.

Two side portions 116 may be arranged next to the front portion 115 on two opposite sides of the front portion 115. The side portions may be curved around the vapor source. The side portions may extend in an essentially vertical orientation.

In some embodiments, the shield 110 may further include two outer portions 117 which form a side edge of the shield 110. The outer portions 117 may extend in an essentially vertical orientation. For example, a first outer portion may be provided next to a first side portion, and a second outer portion may be provided next to a second side portion on an opposite side of the front portion. The two outer portions 117 may extend at an angle with respect to the front portion, e.g. at an angle of 45° or more, particularly about 90°. For example, the two outer portions 117 may extend at least partially essentially parallel to a substrate arranged in the deposition area. The shielding effect of the shield can be improved during a rotation of the vapor source.

The sheet portions of the shield may be configured as consumables. In other words, one or more of the sheet portions may be detachably mounted at the shield, particularly detachably mounted to an adjacent sheet portion and/or to the support frame 111 of the shield. It may be beneficial to periodically exchange and/or clean one or more of the sheet portions, e.g. when a layer of coating material has formed on a surface of a sheet portion. For example, in some embodiments, the front portion 115 may be detachably fixed to the support frame 111 such that the front portion can be demounted from the shield for cleaning. Similarly, the side portions and/or the outer portion may be disconnected from the shield for cleaning and/or exchange. Accordingly, a quick exchange of separate sections or portions of the shield may be possible, e.g. without disconnecting the support frame 111 from the source support. Downtimes of the system can be reduced.

The cooling device 112 may include one or more cooling lines or cooling channels 113 for a cooling fluid for cooling the front portion 115 and/or for cooling other sheet portions of the shield.

In some embodiments, a height of the shield 110 is 1 m or more, particularly 2 m or more. In particular, the height of the shield 110 may be larger than a height of the vapor source 120 so that the evaporated material from the vapor source can be shielded by the shield in the idle position. The vapor source 120 may have a height of 1 m or more, particularly 1.5 m or more.

In some embodiments, which may be combined with other embodiments described herein, a width W of the shield may be 50 cm or more, particularly 1 m or more. The width W may be a maximum dimension of the shield 110 in a horizontal direction, e.g. in a direction perpendicular to the orientation of the substrate 10 during deposition, as is depicted in FIG. 1A and FIG. 1B.

In some embodiments, which may be combined with other embodiments described herein, an average radius of curvature of the shield may be 30 cm or more, particularly 60 cm or more.

FIG. 3 is a schematic sectional view of a part of a deposition system according to embodiments described herein. A vapor source 120 is shown in the idle position in which the evaporated material 15 is directed toward the shield 110, particularly toward the front portion 115 of the shield. The front portion 115 may be cooled by a cooling device such that the temperature of the shield can be kept low and a heat radiation into the deposition area can be reduced.

As is schematically depicted in FIG. 3, two side portions 116 may be arranged next to the front portion 115 on both sides of the front portion 115. The side portions may shield the evaporated material 15 during a movement of the vapor source 120 into and from the idle position. In particular, the vapor source may be rotated into the idle position around a rotation axis, and the shield may extend around the rotation axis in a curved way. Cooling channels may be provided at a support frame of the shield. By providing the cooling channels at the support frame, the sheet portions can be exchanged without exchange of the cooling channels. The front portion 115 may be fixed to a portion of the support frame 111 that includes a portion of the cooling channels 113.

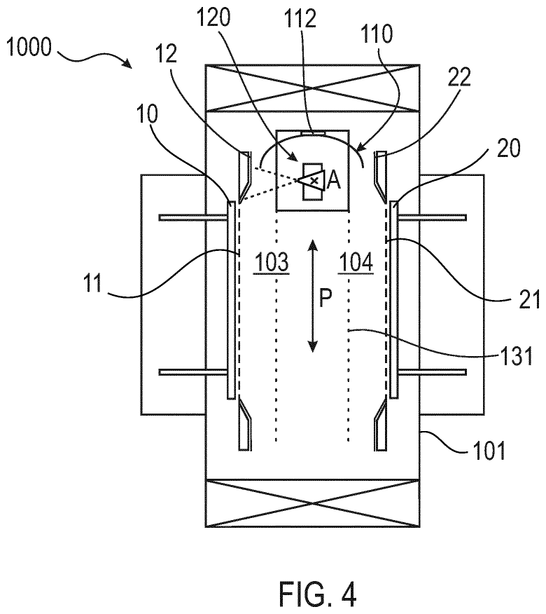

FIG. 4 is a schematic view of a deposition apparatus 1000 according to embodiments described herein. The deposition apparatus includes a vacuum processing chamber 101 with at least one deposition area for arranging a substrate. A sub-atmospheric pressure may be provided in the vacuum processing chamber, e.g. a pressure of 10 mbar or less. A deposition system 100 according to embodiments described herein is arranged in the vacuum processing chamber 101.

In the exemplary embodiment of FIG. 4, two deposition areas are provided in the vacuum processing chamber 101, namely a first deposition area 103 for arranging a substrate 10 to be coated and a second deposition area 104 for arranging a second substrate 20 to be coated. Further, a deposition system 100 according to any of the embodiments described herein is arranged in the vacuum processing chamber 101. The first deposition area 103 and the second deposition area 104 may be provided on opposite sides of the deposition system 100.

In some embodiments, the deposition system 100 includes a vapor source 120 with one or more distribution pipes having one or more vapor outlets for directing plumes of evaporated material toward the substrate. Further, the deposition system 100 includes a shield 110 and a cooling device 112 for cooling the shield 110. The vapor source 120 can be moved from a deposition position that is shown in FIG. 4 into an idle position in which the one or more vapor outlets are directed toward the shield 110. In the deposition position, the one or more vapor outlets are directed to the first deposition area or to the second deposition area.

In some embodiments, which may be combined with other embodiments described herein, the vapor source 120 is movable past the first deposition area 103, rotatable between the first deposition area 103 and the second deposition area 104, and movable past the second deposition area 104. The idle position may be an intermediate rotation position of the vapor source 120 between the first deposition area 103 and the second deposition area 104. In particular, the vapor source may be rotated by about 90°, e.g. clockwise, from the (first) deposition position depicted in FIG. 4 into the idle position. The vapor source may be rotated by about 90° in the same direction, e.g. clockwise, from the idle position into a second deposition position for directing evaporated material toward the second deposition area 104 where the second substrate 20 may be arranged. Alternatively, the vapor source may be rotated back, e.g. counterclockwise, from the idle position to the (first) deposition position.

The vapor source 120 may be movable along a source transportation path P, which may be a linear path. In particular, a first drive may be provided for moving the vapor source 120 together with the shield 110 along the source transportation path P past the first deposition area 103 and/or past the second deposition area 104.

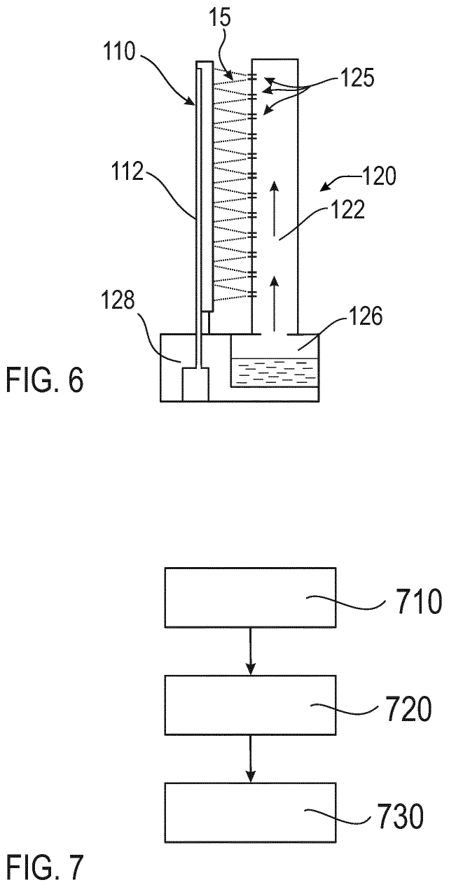

In some embodiments, the shield 110 and the vapor source 120 may be supported on a source support 128, e.g. on a source cart, that is movable along a source track 131 in the vacuum processing chamber 101. An example of a source support 128 that carries the vapor source 120 and the shield 110 is depicted in FIG. 6. The source support 128 may be driven contactlessly along the source tracks 131, e.g. via a magnetic levitation system.

As is depicted in the sectional view of FIG. 6 in more detail, the vapor source 120 may include one, two or more distribution pipes 122 which may extend in an essentially vertical direction. Each distribution pipe of the one, two or more distribution pipes 122 may be in fluid connection with a crucible 126 configured for evaporating a material. Further, each distribution pipe of the one, two or more distribution pipes may include a plurality of vapor outlets 125, e.g. nozzles, arranged along the length of the one, two or more distribution pipes 122. For example, ten, twenty or more vapor outlets may be provided along the length of the distribution pipe, e.g. in an essentially vertical direction. The shield 110 may extend at least partially around the one, two or more distribution pipes of the vapor source. For example, the shield may surround the one, two or more distribution pipes 122 by an angle of 45° or more, particularly 60° or more, more particularly 90° or more. In some embodiments, an opening angle of the plumes of evaporated material propagating from the vapor outlets in a horizontal sectional plane may be between 30° and 60°, particularly about 45°.

FIG. 6 shows a deposition system in the idle position in which the plurality of vapor outlets 125 are directed toward the shield 110. A surface of the shield 110 may be cooled with a cooling device 112. Heat radiation toward the vapor source 120 and toward the deposition area may be reduced.

As is depicted in more detail in FIG. 4, the deposition apparatus 1000 may be configured for the subsequent coating of the substrate 10 arranged in the first deposition area 103 and the second substrate 20 arranged in the second deposition area 104. When the vapor source 120 moves between the deposition areas, the vapor source 120 may stop in the idle position in which the one or more vapor outlets are directed toward the cooled shield. For example, the vapor source 120 may stop for at least one of: service, maintenance, cleaning, waiting, aligning of the substrate or the mask. Alternatively, the vapor source moves continuously between the deposition areas, without stopping in the idle position.

The deposition apparatus 1000 may be configured for masked deposition on one or more substrates. A mask 11 may be arranged in the first deposition area 103 in front of the substrate 10, and/or a second mask 21 may be arranged in the second deposition area 104 in front of the second substrate 20.

In some embodiments, which may be combined with other embodiments described herein, a shielding arrangement 12 may be arranged at a periphery of the mask 11, e.g. adjacent to two opposite sides of the mask 11 in the direction of the source transportation path P, as is depicted in FIG. 4. In some embodiments, the shielding arrangement 12 may surround the mask 11 in a frame-like manner. The shielding arrangement may consist of a plurality of shielding units which may be attached to a mask carrier that holds the mask 11. For example, the shielding arrangement 12 may be detachably attached at a periphery of the mask such as to be easily and quickly exchangeable, e.g. for cleaning.

The shielding arrangement 12 may be configured for shielding evaporated material which is directed from the one or more vapor outlets toward a periphery of the mask 11. A coating of the mask carrier and/or of a wall of the vacuum processing chamber 101 can be reduced or avoided. For example, after the deposition on the substrate 10, the evaporated material may be directed toward the shielding arrangement 12 which may extend essentially parallel to the substrate 10 and which may be arranged adjacent to the mask 11 along the source transportation path P. In the deposition position depicted in FIG. 4, evaporated material is directed toward the shielding arrangement 12. Thereafter, the vapor source 120 may rotate toward the idle position, and the evaporated material may be directed toward the shield 110. Cleaning efforts can be reduced.

In some embodiments, the shielding arrangement 12 is arranged next to the mask 11 in the first deposition area 103, and a second shielding arrangement 22 is arranged next to the second mask 21 in the second deposition area 104. For example, the second shielding arrangement 22 is arranged at a periphery of the second mask 21 and configured for shielding evaporated material directed toward the periphery of the second mask 21. In particular, the shielding arrangement 12 may be arranged in the first deposition area 103 for shielding evaporated material directed to the periphery of the mask 11 in the first deposition area 103, and the second shielding arrangement 22 may be arranged in the second deposition area 104 for shielding evaporated material directed to the periphery of the second mask 21 in the second deposition area 104. During the movement of the vapor source between the deposition areas, the shield 110 may shield the evaporated material.

In some embodiments, a minimum distance between the shielding arrangement 12 and the shield 110 may be 10 cm or less, particularly 5 cm or less, more particularly 2 cm or less, and/or a minimum distance between the second shielding arrangement 22 and the shield 110 may be 10 cm or less, particularly 5 cm or less, more particularly 2 cm or less. Sprinkle coating past the shielding surfaces of the shield and of the shielding arrangement at a transition between the shield and the shielding arrangement can be reduced or avoided. In particular, the shield may extend over more than 50%, particularly over more than 80%, of a width of the vacuum processing chamber 101 between the mask 11 and the second mask 21.

In some embodiments, which may be combined with other embodiments described herein, a minimum distance between the vapor source 120 and the shield 110 during a movement of the vapor source from the deposition position to the idle position is 5 cm or less, particularly 1 cm or less. In other words, the vapor source 120 and the shield 110 may come close to each other during the rotation of the vapor source into the idle position.

In some embodiments, which can be combined with other embodiments described herein, a distance between the one or more vapor outlets and the substrate during the deposition on the substrate may be 30 cm or less, particularly 20 cm or less, more particularly 15 cm or less. A small distance between the vapor outlets and the substrate leads to a small overrun of the evaporated material in an edge region of the mask 11 during deposition. Therefore, a more compact shielding arrangement can be provided, since an area of the evaporation plume which hits the mask and the substrate may be small. Further, the deposition quality may be increased.

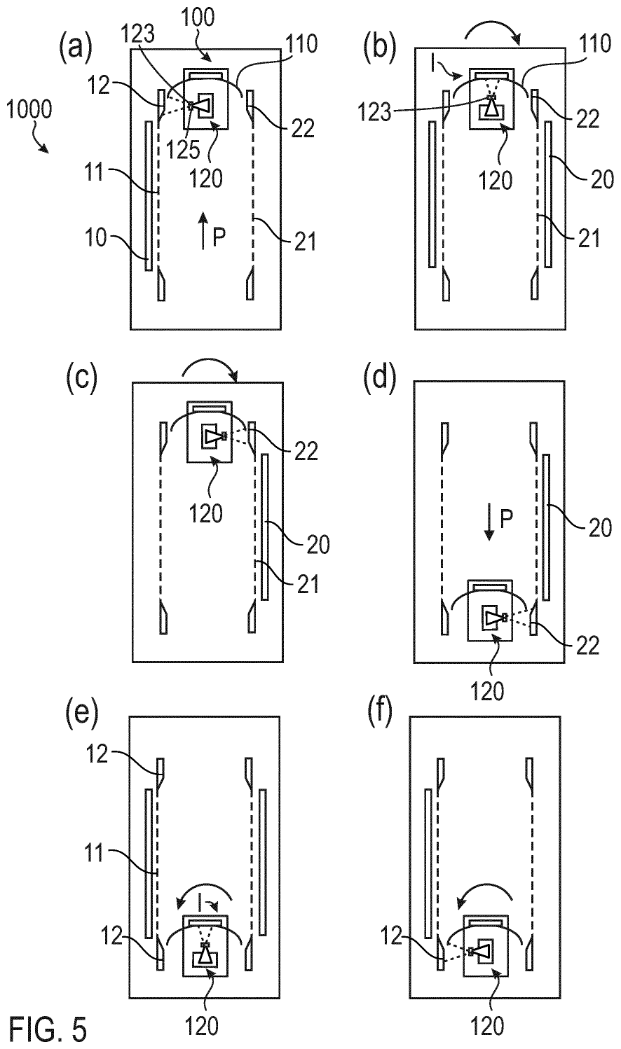

FIG. 5 shows stages (a) to (f) of a method of operating a deposition system according to embodiments described herein. The deposition system may correspond to the deposition system of FIG. 4, so that reference can be made to the above explanations, which are not repeated here.

In stage (a) of FIG. 5, the vapor source 120 is in a first deposition position in which the one or more vapor outlets 125 of the vapor source 120 are directed toward the first deposition area. A material pattern is deposited on the substrate 10 through the mask 11 while the vapor source 120 is moved together with the shield 110 past the substrate 10 along the source transportation path P.

After the deposition on the substrate 10, the evaporated material is directed toward the shielding arrangement 12 that is arranged at a periphery of the mask. The shielding arrangement may be a detachable component that can be easily exchanged and/or cleaned. The coating of a mask carrier and/or of a wall of the vacuum processing chamber 101 can be reduced or avoided by the shielding arrangement 12. The shielding arrangement 12 may comprise shielding units which are attached to a mask carrier configured for holding and transporting the mask 11.

In stage (b) of FIG. 5, the vapor source 120 is rotated to the idle position (I) in which the one or more vapor outlets 125 are directed towards the shield 110, e.g. clockwise by an angle of about 90°. In some embodiments, the vapor source 120 may remain in the idle position for a predetermined time period. For example, the vapor source may be at least locally heated in the idle position in order to clean the vapor source.

In some embodiments, which may be combined with other embodiments described herein, shaper shields 123 for shaping the plumes of evaporated material propagating from the one or more vapor outlets 125 may be arranged in front of the one or more vapor outlets 125. For example, the shaper shields 123 may be attached to one or more distribution pipes of the vapor source 120 and may be provided with apertures for shaping the evaporation plumes. During deposition, a part of the evaporated material may be blocked by and attach to the shaper shields 123. In the idle position (I) of the vapor source, the shaper shields 123 may be cleaned by at least locally heating the shaper shields 123 for releasing at least a part of the attached material from the shaper shields 123. The material released from the shaper shields 123 during the heating may propagate toward the cooled shield 110 and condense thereon. For example, in some embodiments, heaters for heating the shaper shields 123 may be attached to or integrated in the shaper shields. The heaters may be thermoelectric heaters.

In some embodiments, the vapor source 120 may remain in the idle position for ten seconds or more, particularly for twenty seconds or more. For example, the vapor source 120 may remain in the idle position (I) for at least one of: locally heating the vapor source for cleaning, alignment of the substrate, alignment of the mask, positioning of the substrate, positioning of the mask, transport of a coated substrate out of the vacuum processing chamber, transport of an uncoated substrate into the vacuum processing chamber, waiting for synchronization with a cycle frequency of the deposition process, parking or shut-down of the vapor source.

In stage (c) of FIG. 5, the vapor source 120 is rotated from the idle position towards a second deposition position, e.g. clockwise by an angle of about 90°. In the second deposition position, the one or more vapor outlets 125 of the vapor source are directed towards the second deposition area which may be arranged opposite the first deposition area. A second substrate 20 to be coated may be arranged in the second deposition area. A second mask 21 may be arranged in front of the second substrate 20.

A second shielding arrangement 22 may be provided at a periphery of the second mask 21. The second shielding arrangement 22 may be configured for shielding the evaporated material directed towards the periphery of the second mask 21. The second shielding arrangement 22 may comprise shielding units which are attached to a mask carrier configured for holding and transporting the second mask 21.

In stage (d) of FIG. 5, the vapor source 120 is moved together with the shield 110 along the source transportation path P while a material pattern is deposited on the second substrate 20. The second shielding arrangement 22 shields evaporated material which is directed from the one or more vapor outlets toward a periphery of the second mask 21. While the second substrate 20 is coated, a further substrate may be transported into the first deposition area and be aligned with respect to the mask 11.

In stage (e) of FIG. 5, the vapor source 120 is rotated with respect to the shield 110 into the idle position (I), e.g. counterclockwise by an angle of about 90°. During the movement of the vapor source into the idle position, an outer portion of the shield 110 may shield the evaporated material which is directed from the one or more vapor outlets toward the second mask 21 and/or toward the second substrate 20. In other words, the shield may prevent evaporated material from hitting the already coated second substrate 20 and/or the second mask 21 during the rotation of the vapor source.

The vapor source 120 may stop in the idle position, e.g. for locally cleaning the vapor source. Alternatively, the vapor source 120 may rotate toward the first deposition area without stopping at the idle position. The idle position may be used as a parking position of the vapor source whenever needed, e.g. for pausing the deposition process.

In stage (f) of FIG. 5, the vapor source is rotated from the idle position towards the first deposition area, e.g. counterclockwise by an angle of about 90°. The evaporated material may be directed toward the shielding arrangement 12 which is arranged at the periphery of the mask 11 and prevent a contamination of a mask carrier which holds the mask 11.

Thereupon, the vapor source 120 may be moved past the first deposition area along the source transportation path toward the position shown in stage (a) of FIG. 5.

According to a further aspect described herein, a method of operating a deposition system is described. The deposition system may be a deposition system according to any of the embodiments described herein. In particular, the deposition system includes a vapor source with one or more vapor outlets, wherein the vapor source is movable into an idle position.

FIG. 7 is a flow diagram which schematically illustrates a method of operating a deposition system. In box 710, evaporated material is directed from the one or more vapor outlets of the vapor source toward a substrate. The vapor source may be provided in a deposition position in which the one or more vapor outlets of the vapor source are directed toward a deposition area. A mask may be arranged between the vapor source and the substrate so that a material pattern corresponding to an opening pattern of the mask can be deposited on the substrate.

In box 720, the vapor source is moved to an idle position in which evaporated material from the one or more vapor outlets is directed toward a cooled shield.

In box 730, the vapor source is moved from the idle position back to the deposition position or to a further deposition position in which the one or more vapor outlets are directed toward a further deposition area.

In box 720, when the vapor source is in the idle position, a portion of the vapor source which is directed toward the cooled shield may be heated. For example, the vapor source is locally heated for locally cleaning the vapor source in the idle position. Shaper shields arranged in front of the one or more vapor outlets can be cleaned.

Moving the vapor source to the idle position may include rotating the vapor source around a rotation axis, particularly by an angle of about 90° from the deposition position, wherein evaporated material from the one or more outlets is subsequently shielded by a shielding arrangement provided at a periphery of a mask and the shield.

The shielding arrangement may be fixed to a mask carrier that is configured for holding and transporting the mask. The shielding arrangement may include a plurality of shielding units provided next to the mask and/or surrounding the mask, e.g. in a frame-like manner.

During the rotation of the vapor source into the idle position, first an outer portion of the shield may shield the evaporated material. Then, a side portion of the shield may shield the evaporated material. Finally, a cooled front portion of the shield may shield the evaporated material. In the idle position, the one or more vapor outlets may be directed toward the front portion of the shield.

While the foregoing is directed to embodiments of the disclosure, other and further embodiments of the disclosure may be devised without departing from the basic scope thereof, and the scope thereof is determined by the claims that follow.

1. A deposition system, comprising:
a vapor source having one or more vapor outlets, the vapor source movable between a deposition position and an idle position;
a shield; and
a cooling device positioned to cool the shield, wherein the one or more vapor outlets are directed toward the shield in the idle position.

2. (canceled)

3. The deposition system of claim 1, further comprising:
at least one of a first drive for moving the vapor source together with the shield along a transportation path and a second drive for moving the vapor source relative to the shield to the idle position.

4. (canceled)

5. The deposition system of claim 1, wherein the vapor source is rotatable relative to the shield around a rotation axis.

6. The deposition system of claim 5, wherein the rotation axis is an essentially vertical rotation axis.

7. The deposition system of claim 1, wherein the cooling device is configured for cooling a front portion of the shield to which the one or more vapor outlets are directed when the vapor source is in the idle position.

8. The deposition system of claim 1, wherein the shield comprises one or more curved portions extending partially around the vapor source.

9. The deposition system of claim 1, wherein the shield extends around the vapor source by an angle of 30° or more.

10. The deposition system of claim 1, wherein the shield comprises a plurality of shielding portions formed as sheet elements.

11. The deposition system of claim 1, wherein the shield comprises one or more of:
a bottom portion which extends in an essentially horizontal orientation at a position below the one or more vapor outlets;
a top portion which extends in an essentially horizontal orientation at a position above the one or more vapor outlets;
a front portion which extends in an essentially vertical orientation in front of the one or more vapor outlets, when the vapor source is in the idle position;
two curved side portions which extend in an essentially vertical orientation on two opposite sides of the front portion; and
two outer portions which extend in an essentially vertical orientation and form an edge of the shield.

12. The deposition system of claim 1, wherein the cooling device comprises one or more cooling channels.

13. The deposition system of claim 1, wherein a distance between the one or more vapor outlets and the shield is between about 5 cm and about 30 cm, when the vapor source is in the idle position.

14. The deposition system of claim 1, wherein a minimum distance between the vapor source and the shield during a movement of the vapor source between a deposition position and the idle position is 5 cm or less.

15. The deposition system of claim 1, wherein a height of the shield is 1 m or more, or a width of the shield is 50 cm or more.

16. The deposition system of claim 1, wherein the vapor source includes one, two or more distribution pipes extending in an essentially vertical direction and a plurality of vapor outlets arranged along a length of the one, two or more distribution pipes.

17. A deposition apparatus, comprising:
a vacuum processing chamber with a first deposition area for arranging a substrate and a second deposition area for arranging a second substrate; and
a deposition system according to claim 1 arranged in the vacuum processing chamber, wherein the vapor source of the deposition system is movable past the first deposition area, rotatable between the first deposition area and the second deposition area, and movable past the second deposition area.

18. The deposition apparatus of claim 17, further comprising a shielding arrangement configured for shielding evaporated material directed toward a periphery of a mask.

19. A method of operating a deposition system according to claim 1, comprising:
directing evaporated material from one or more vapor outlets of a vapor source toward a substrate; and
moving the vapor source to an idle position in which evaporated material from the one or more vapor outlets is directed toward a cooled shield.

20. The method of claim 19, further comprising:
heating a portion of the vapor source when the vapor source is in the idle position.

21. The method of claim 19, wherein moving the vapor source to the idle position comprises rotating the vapor source around a rotation axis from a deposition position, wherein evaporated material from the one or more vapor outlets is subsequently shielded by:
a shielding arrangement provided at a periphery of a mask;
an outer portion of the shield; and
a cooled front portion (115) of the shield.

22. The deposition system of claim 8, wherein the one or more curved portions comprise two side portions arranged on opposite sides of the front portion.
